(19) United States
(12) Patent Application Publication
(10) Pub. No.: US 2025/0102908 A1
(43) Pub. Date: Mar. 27, 2025

(54) ORGANOTIN PHOTORESIST COMPOSITION AND METHOD OF FORMING PHOTOLITHOGRAPHY PATTERN

(71) Applicant: Feng Lu, Irvine, CA (US)

(72) Inventor: Feng Lu, Irvine, CA (US)

(21) Appl. No.: 18/764,319

(22) Filed: Jul. 4, 2024

Related U.S. Application Data
(60) Provisional application No. 63/528,170, filed on Jul. 21, 2023.

(51) Int. Cl. G03F 7/004; C07F 17/00

(52) U.S. Cl. CPC G03F 7/0042; C07F 17/00

(57) ABSTRACT

An organotin photoresist composition and a method of forming photolithography pattern are described. The organotin photoresist composition comprises a bridged-(stannocenyl)tin compound, a solvent, and/or an additive. Stannocenyl comprises bis(cyclopentadienyl)tin, or substituted bis(cyclopentadienyl)tin, wherein cyclopentadienyl is cyclopentadienyl C₅H₅ group, or substituted cyclopentadienyl C₅H₃R, C₅H₂R₂, C₅HR₃, or C₅R₄ group. A method of forming the pattern comprises: depositing bridged-(stannocenyl)tin compound photoresist over a substrate to form a photoresist layer, exposing the photoresist layer to actinic radiation to form a latent pattern, and then developing to form photolithography pattern.

### CROSS REFERENCE TO RELATED APPLICATIONS

This application claims priority to U.S. provisional patent application No. 63/528,170 filed on Jul. 21, 2023 to Lu, entitled “Organotin photoresist composition and method of forming photolithography pattern”, of which is entirely incorporated herein by reference.

### FIELD OF INVENTION

The present invention pertains to organotin photoresist composition and method of forming photolithography pattern. The organotin photoresist composition comprises bridged-(stannocenyl)tin compound, a solvent, and/or an additive. Stannocenyl comprises bis(cyclopentadienyl)tin, or substituted bis(cyclopentadienyl)tin.

### BACKGROUND

With the development of the semiconductor industry, nanoscale patterns have been in pursuit of higher devices density, higher performance, and lower costs. Reducing semiconductor feature size has become a grand challenge. Photolithography has been applied for creating microelectronic patterns over decades. Extreme ultraviolet (EUV) lithography is under development for mass production of smaller semiconductor devices feature size and increasement of devise density on a semiconductor wafer. EUV lithography is a pattern-forming technology using wavelength of 13.5 nm as an exposure light source to manufacture high-performance integrated circuits containing high-density structures patterned with nanometer scale. The application of EUV lithography can make extremely fine pattern with smaller width as equal to or less than 7 nm. Therefore, EUV lithography becomes one significant tool and technology for manufacturing next generation semiconductor devices.

In order to improve EUV lithography for smaller level, wafer exposure throughput can be improved through increased exposure power or increased photoresist sensitivity. Photoresists are radiation sensitive materials upon irradiation with relevant chemical transformation occurs in the exposed region, which would result in different properties between the exposed and unexposed regions. The properties of EUV photoresist, such as resolution, sensitivity, line edge roughness (LER), line width roughness (LWR), etch resistance and ability to form thinner layer are important in photolithography.

Organometallic compounds have high ultraviolet light adsorption because metals have high adsorption capacity of ultraviolet radiation with various carbon-metal (C-M) bond dissociation energy (BDE), and then can be used as photoresists and/or the precursors for photolithography at smaller level (e.g., <7 nm), which is of great interests for radiation lithography. Among those promising advanced materials, particularly organometallic tin compounds can provide photoresist patterning with significant advantages, such as improved resolution, sensitivity, etch resistance, and lower line width/edge roughness without pattern collapse because of strong EUV radiation adsorption of tin, which have been demonstrated.

In some embodiments, organometallic metallocene-based compounds can be sublimized or vaporized under high vacuum and temperature. Therefore, organometallic metallocene-based compound photoresists, for example, (stannocenyl)tin compound, can be deposited on the surface of semiconductor substrate by chemical vapor deposition (CVD), physical vapor deposition (PVD), or atomic layer deposition (ALD). In some embodiments, the organometallic compound photoresist composition can be deposited on the substrate by spin-on coating, spray coating, or other approaches to form photoresist layer. In some embodiments, the organometallic compound photoresist or precursor can react with the introduced oxygen-source compound to form organotin photoresist layer on the substrate, wherein oxygen-source compound is one or more selected from the group consisting of water, oxygen, extremely clean air, ozone, or hydrogen peroxide. After exposing the organotin photoresist layer to actinic radiation, such as EUV 13.5 nm, to form a latent pattern; and followed by developing the latent pattern by applying a developer, or sublimation method, to remove the selected portion of photoresists to form a photolithography pattern. The exposed and unexposed portion of organometallic compound photoresist have different properties and solubility in organic solvents or aqueous, for example, becoming non-sublimized or non-volatile or insoluble metallic complexes or polymetallic network complexes, such as metal oxides, or metal oxide/hydroxide network complexes. As a result, the exposed or unexposed portion can be selectively removed by a developer, or sublimation, or vaporization to form photolithography pattern.

### SUMMARY

In a first aspect, the present invention pertains to organotin photoresist composition and method of forming photolithography patterning. The present invention is to provide bridged-(stannocenyl)tin compound photoresist composition for photolithography patterning, including extreme ultraviolet (EUV) and deep ultraviolet (DUV).

In another aspect, the invention relates to radiation sensitive organotin photoresist composition, which can be efficiently patterned in the presence of ultraviolet light, extreme ultraviolet light, deep ultraviolet, or electron beam to form high resolution patterns with low line width roughness at <7 nm, and with high resolution, low dose and large contrast for <7 nm.

In a further aspect, the invention pertains to radiation sensitive bridged-(stannocenyl)tin compounds, wherein stannocenyl comprises bis(cyclopentadienyl)tin, or substituted bis(cyclopentadienyl)tin; wherein cyclopentadienyl comprises cyclopentadienyl C₅H₅ group, or substituted cyclopentadienyl C₅H₃R, C₅H₂R₂, C₅HR₃, or C₅R₄ group, wherein R is H, a substituted or unsubstituted alkyl, alkenyl, alkynyl, or a cycloalkyl group with 1 to 20 carbon atoms, or a substituted or unsubstituted aryl group with 6-20 carbon atoms, or an amine, cyano, ether, cyclic ether, ester, cyclic ester, halide, nitro, silyl, thiol, or carbonyl group.

In other aspects, the present invention pertains to a method of forming photolithography pattern comprising: depositing organotin compound photoresist over a substrate to form a layer, wherein organotin compound is bridged-(stannocenyl)tin compound; exposing the formed photoresist layer to actinic radiation to form a latent pattern; and then developing the latent pattern by applying a developer, or sublimation, or evaporation to remove the selected portion of photoresists to form a photolithography pattern.

In some embodiments, the invention pertains to photolithography irradiation process, bridged-(stannocenyl)tin compounds may also be applied as precursors under oxygen source atmosphere, including but not limited to water (H₂O), oxygen (O₂), extremely clean air, ozone (O₃), or hydrogen peroxide (H₂O₂), to form photoresist layer on the substrate, which can result in or enhance the oxidization of irradiated organotin photoresist to form metal oxide or polymetallic oxide networks under some circumstances.

The invention pertains to radiation sensitive bridged-(stannocenyl)tin compound photoresist composition, which are suitable for photolithography patterning, such as EUV or DUV, and/or as the precursors for EUV or DUV photolithography. In some embodiments, bridged-(stannocenyl)tin compound photoresist can be sublimized or vaporized under reduced pressure ranging from 0.00001 torr to 100 torr, and temperature ranging from 20 to 300° C.

In an additional aspect, the invention pertains to synthesize of radiation sensitive bridged-(stannocenyl)tin compounds, in which bis(cyclopentadienyl)tin ((η⁵—C₅H₅)₂Sn, stannocene, or Sc) is used as parent molecule for carrying out lithiation at one or two C₅ rings (i.e., mono-lithiation, or bi-lithiation) by strong bases, for example, methyllithium (MeLi), n-butyllithium (n-BuLi), s-butyllithium (s-BuLi), or t-butyllithium (t-BuLi), then followed by appropriate procedures to synthesize bridged-(stannocenyl)tin compounds.

Examples of organometallic bridged-(stannocenyl)tin compounds for the implementations of the invention are represented by Chemical Formulas (1)-(46) as below:

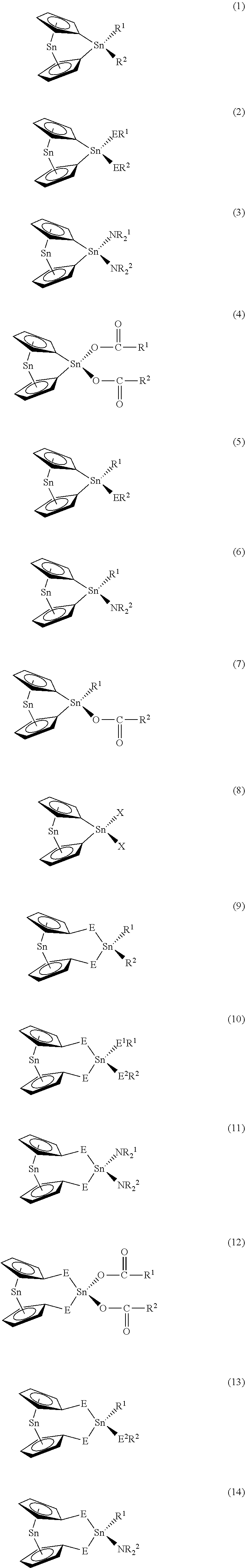

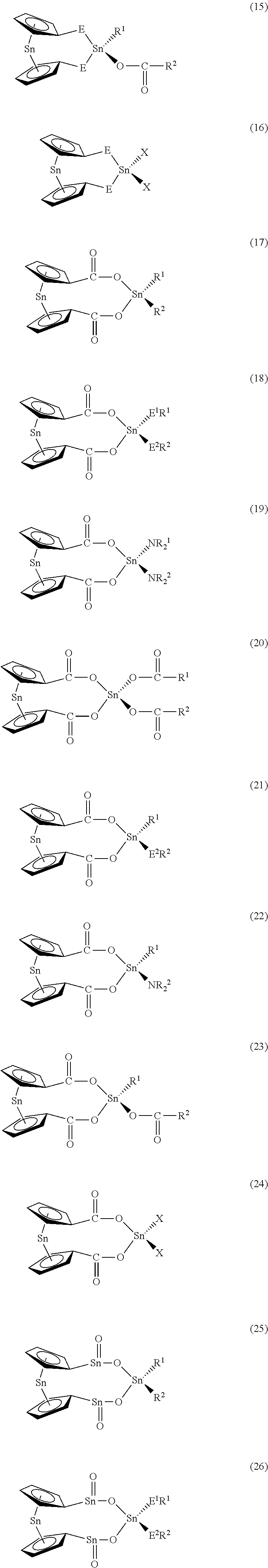

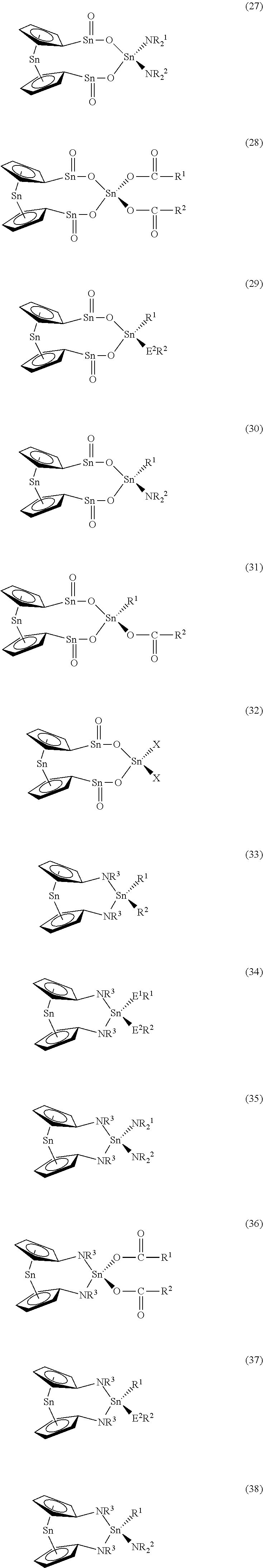

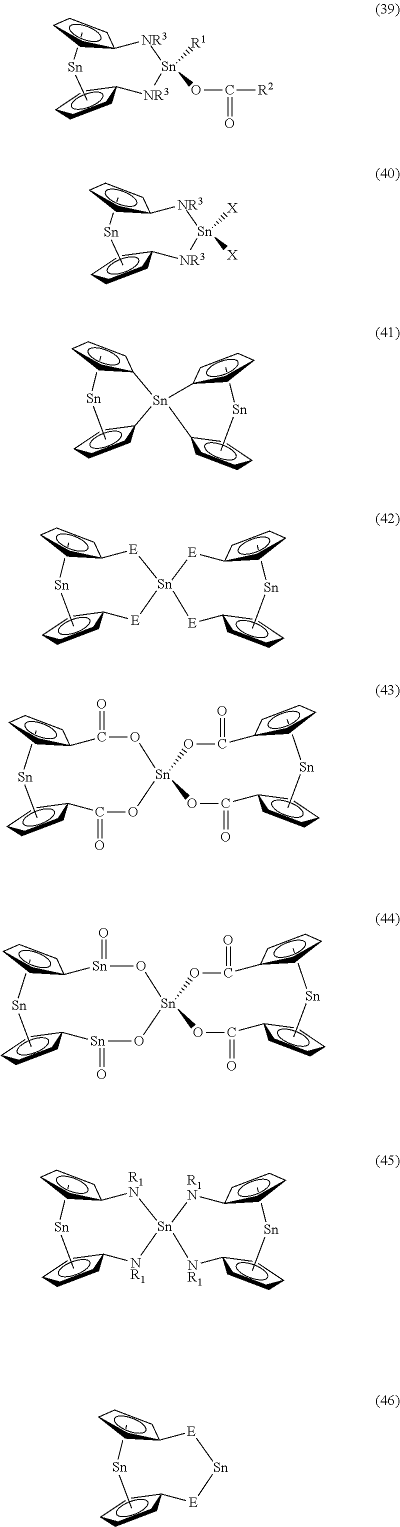

wherein R¹, R², R³ are each independently H, substituted or unsubstituted an alkyl, alkenyl, alkynyl, cycloalkyl, or cycloalkenyl group with 1 to 20 carbon atoms, or a substituted or unsubstituted aryl group with 6-20 carbon atoms, wherein cycloalkenyl group comprises a substituted and unsubstituted C4 to C8 cyclic aliphatic unsaturated organic groups including at least one double bond, E, E¹, E² are each independently O, S, Se, or Te, X═F, Cl, Br, or I.

In a further aspect, the invention pertains to methods of organotin photoresist deposition over a surface of semiconductor substrate by wet deposition like spin-on coating, spray coating, or dry deposition like chemical vapor deposition, or physical vapor deposition, or atomic layer deposition, or other approaches.

The invention pertains to a method of developing photolithography pattern including sublimation or vaporization, which may have advantages for smaller features of photolithography patterning (e.g., at <7 nm, particularly 1-3 nm), compared to conventional wet liquid solvents development methods or dry gaseous development methods. The wetting and surface tension on the semiconductor substrate surface may make the conventional development methods difficult at smaller patterning, along with pattern collapses and defects due to the liquid flows or gaseous flows or rinse process. The development process may be accomplished by sublimation or vaporization under high vacuum and ambient temperature for the pattern development without collapse and defects. The photosensitivity and thermostability of organotin photoresists determine high resolution and efficiency of photolithography.

### BRIEF DESCRIPTION OF THE DRAWINGS

FIG. 1 illustrates a flowchart of organotin photoresist radiation photolithography patterning processing on a surface of semiconductor substrate, including organotin photoresist compositions deposition over the substrate, and/or pre-exposure baking, exposing to actinic radiation, and then development.

### DETAILED DESCRIPTION

The present invention relates to organotin photoresist composition and a method of forming photolithography pattern; wherein organotin photoresist composition comprises bridged-(stannocenyl)tin compound, a solvent, and/or an additive. Stannocenyl is bis(cyclopentadienyl)tin, or substituted bis(cyclopentadienyl)tin, wherein cyclopentadienyl comprises cyclopentadienyl C₅H₅ group, or substituted cyclopentadienyl C₅H₃R, C₅H₂R₂, C₅HR₃, C₅R₄, or C₅R₅ group. The method of forming photolithography patterning comprises depositing organotin compound photoresist composition over a substrate to form a layer; exposing the layer to actinic radiation to form a latent pattern; and developing the latent pattern to form a photolithography patterning.

As described herein, the singular forms “a”, “an”, “one”, and “the” are intended to include the plural forms as well, unless clearly indicated otherwise. Further, the expression “one of,” “at least one of,” “any”, and “selected from,” when preceding a list of elements, modify the entire list of elements and do not modify the individual elements of the list.

As described herein, the terms “includes”, “including”, “comprise”, or “comprising”, when used in this specification, specify the presence of the stated features, steps, operations, elements, components, but do not preclude the presence or addition of one or more other features, steps, operations, elements, components, and/or group thereof.

As described herein, the term “and/or” includes any and all combinations of one or more of the associated listed items. Further, the use of “may” when describing embodiments of the present disclosure refers to “one or more embodiments of the present disclosure”.

As described herein, the terms “use,” “using,” and “used” may be considered synonymous with the terms “utilize,” “utilized”, “applied”, respectively. In addition, the terms “about,” “only,” and similar terms are used as terms of approximation and not as terms of degree, and are intended to account for the inherent deviation in measured or calculated values that would be recognized by those of ordinary skill in the art.

The terms “alkyl, alkenyl, or alkynyl” refers to hydrocarbon of 1 to 20 carbon atoms. The terms “cycloalkyl, or cycloalkenyl” refers to cyclic hydrocarbon of 3 to 20 carbon atoms. The term “aryl” refers to unsubstituted or substituted aromatic group with 6-20 carbon atoms. The term “alkylene” refers to a saturated divalent hydrocarbons by removal of two hydrogen atoms from a saturated hydrocarbons of 1 to 20 carbon atoms, e.g., methylene (—CH₂—), ethylene (—CH₂CH₂—), propylene (—CH₂CH₂CH₂—), or the like.

In some embodiments, cycloalkenyl group comprises a substituted and unsubstituted C4 to C8 cyclic aliphatic unsaturated organic groups including at least one double bond. In some embodiments, cycloalkenyl is one or more selected from the following:

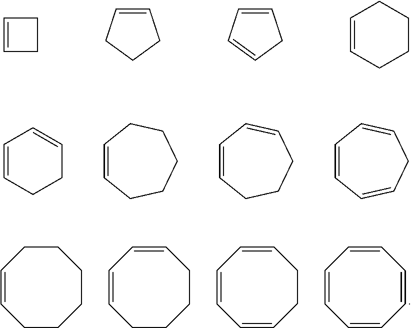

The term “amine” refers to primary (—NH₂), secondary (—NHR), tertiary (—NR₂) amine group. The term “cyclic amine” refers to [R—NH—R′], wherein [R—R′] is cyclic substituted and unsubstituted C3 to C8 organic groups, including, but not limited to:

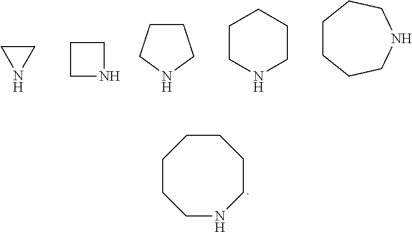

The term “ether” refers to the R—O—R′ group. The term “cyclic ether” refers to the [R—O—R′], wherein [R—R] is cyclic substituted and unsubstituted C3 to C8 organic groups, including, but not limited to:

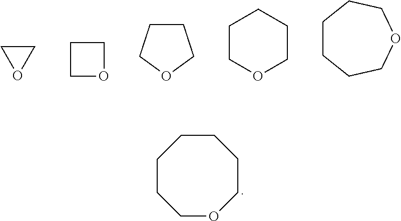

The term “ester” refers to the R—(C═O)—O—R′ group. The term “cyclic ester” refers to the [R—(C═O)—O—R′], wherein [R—R′] is cyclic substituted and unsubstituted C4 to C8 organic groups, including, but not limited to:

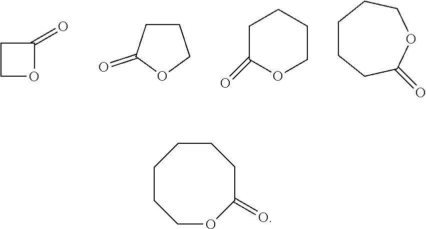

The term “halide” refers to the F, Cl, Br, or I. The term “nitro” refers to the —NO₂. The term “silyl” refers to the SiR′—, —SiR′₂—, or —SiR′₃ group. The term “thiol” refers to —SH group. The term “carbonyl” refers to the —C═O group. The term “oxo” refers to —O—, or ═O.

In the above described, R, R′ are independently a substituted or unsubstituted alkyl, alkenyl, alkynyl, cycloalkyl, or cycloalkenyl group with 1 to 20 carbon atoms, or a substituted or unsubstituted aryl group with 6-20 carbon atoms.

The term “substituted” refers to replacement of a hydrogen atom with a C1 to C20 alkyl group, a C1 to C20 alkene group, a C1 to C20 alkyne group, a C1 to C20 cycloalkyl group, a C6 to C20 aryl group, or other relevant groups, such as amide, amine, cyclic amine, cyano, ether, cyclic ether, ester, cyclic ester, halide, imine, nitro, silyl, thiol, or carbonyl group.

The terms “η¹” refers to one carbon atom bonded to one metal atom. The terms “η²” refers to two carbon atoms bonded to one metal atom. The terms “η³” refers to three carbon atoms bonded to one metal atom. The terms “η⁴” refers to four carbon atoms bonded to one metal atom. The terms “η⁵,” refers to five carbon atoms bonded to one metal atom. In some embodiments, η⁵-organometallic compounds comprise half-sandwich or sandwich-type compounds bearing η⁵—C₅—Sn π bond.

EUV lithography is under the development for the mass production of next generation <7 nm node. EUV photoresists are required to achieve higher performance, higher sensitivity and resolution, and cost reduction.

EUV light has been applied for photolithography at about 13.5 nm. In some embodiments, the EUV light can be generated from Sn plasma or Xe plasma source excited using high energy lasers or discharge pulses.

For conventional organic polymer photoresists, if the aspect ratio, which is the height divided by width, is too large that would lead to pattern structures susceptible to collapse, and also associated with surface tension, which would limit the application for smaller features like <7 nm.

For small feature sizes like <7 nm such as 1-3 nm, the conventional chemically amplified (CA) organic polymer photoresists encounter critical issues such as poor EUV light adsorption, low resolution, high line edge roughness (LER), increased pattern collapses and defects. In order to overcome the disadvantages from organic polymer photoresists, organometallic photoresists and relevant organometallic photosensitive compositions, particularly for EUV, have been called for.

Organometallic photoresists can be used in EUV lithography because metals have high adsorption capacity of EUV radiation. Radiation sensitivity and thermal-, oxygen- and moisture-stability are important for organometallic photoresists. In some embodiments, organometallic photoresists may adsorb moisture and oxygen, which may result in decreasing stability, as well decreasing solubility in developer solutions. In addition, in some embodiments, photoresist layer may outgas volatile components prior to the radiation exposure and development operations, which may negatively affect the photolithography performance, lead to pattern collapse and defects.

The physical and chemical properties of organometallic compounds which are suitable for photoresists determine the relevant properties for photolithography, particularly for EUV and DUV, wherein bond dissociated energy (BDE) of M-C(metal-carbon bond) plays the key role. M is metal including but not limited to, tin (Sn), indium (In), antimony (Sb), bismuth (Bi), manganese (Mn), vanadium (V), titanium (Ti), chromium (Cr), selenium (Se), tellurium (Te), zirconium (Zr), hafnium (Hf), gallium (Ga), or germanium (Ge). Particularly, organotin photoresists are suitable for EUV or DUV photolithography.

In general, metal central plays the key role in determining the absorption of photo radiation of organometallic photoresists. Tin atom provides strong absorption of extreme ultraviolet (EUV) light at 13.5 nm, therein tin cations can be selected based on the desired radiation and absorption cross section. The organic ligand bonded to tin also has absorption of EUV light. The tuning and modification of organic ligands can change sensitivity, radiation absorption, and the desired control of material properties.

The bond dissociation energy (BDE) of Sn—C bond determines the light adsorption wavelength, corresponding smaller features, and patterned structures.

Organotin photoresists, including bridged-(stannocenyl)tin compound photoresists, have excellent (e.g., suitable) sensitivity to high energy light (e.g., EUV, X-ray, or laser) due to tin strong absorption of extreme ultraviolet (EUV) at about 13.5 nm. Accordingly, organotin photoresists have improved sensitivity, resolution and stability compared to conventional organic polymer, and/or inorganic photoresists.

In some embodiments, organotin photoresists comprise small organometallic tin compounds, organotin clusters, organotin nanoparticles, or organotin polymers.

Organotin photoresists comprise organic ligand, Sn—C bond, or Sn—O bond, or Sn—O—Sn bond, or Sn—N bond, or Sn—S bond, or Sn—Se bond, or Sn—Te bond, providing desirable radiation sensitive and stabilization for photolithography patterning.

Organotin photoresist composition according to embodiments of the present disclosure may have improved etch resistance, sensitivity and resolution, compared to relevant conventional organic polymer or inorganic resists, wherein oxygen, nitrogen, or various groups are bonded to tin metal as described above.

Organotin photoresist layer is patterned by exposure to actinic radiation. Typically, the chemical properties of the photoresist regions struck by incident radiation change in a manner that depends on the type of photoresist used. Photoresist can be positive resist or negative resist. In some embodiments, positive resist refer to a photoresist material that when exposed to radiation (e.g., EUV) becomes soluble in a developer, while the region of the photoresist that is non-exposed (or exposed less) is insoluble in the developer. In some embodiments, on the contrary, negative resist refers to a photoresist material that when exposed to radiation becomes insoluble in the developer, while the region of the photoresist that is non-exposed (or exposed less) is soluble in the developer.

Examples of specific bridged-(stannocenyl)tin compounds are represented by the Chemical Formulas of (1)-(46) as the following:

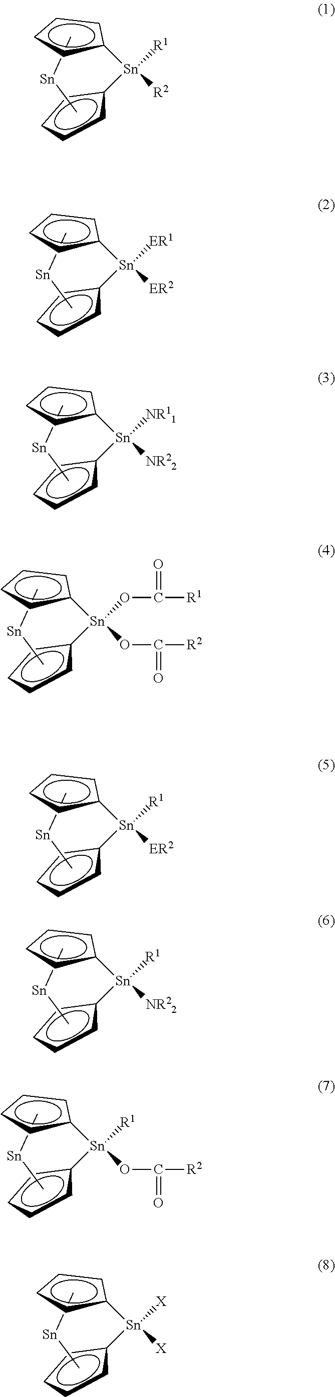

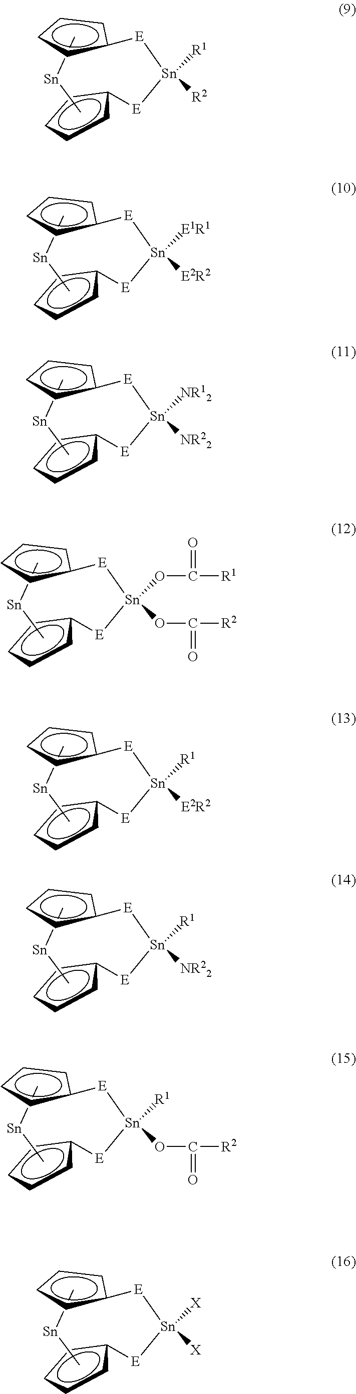

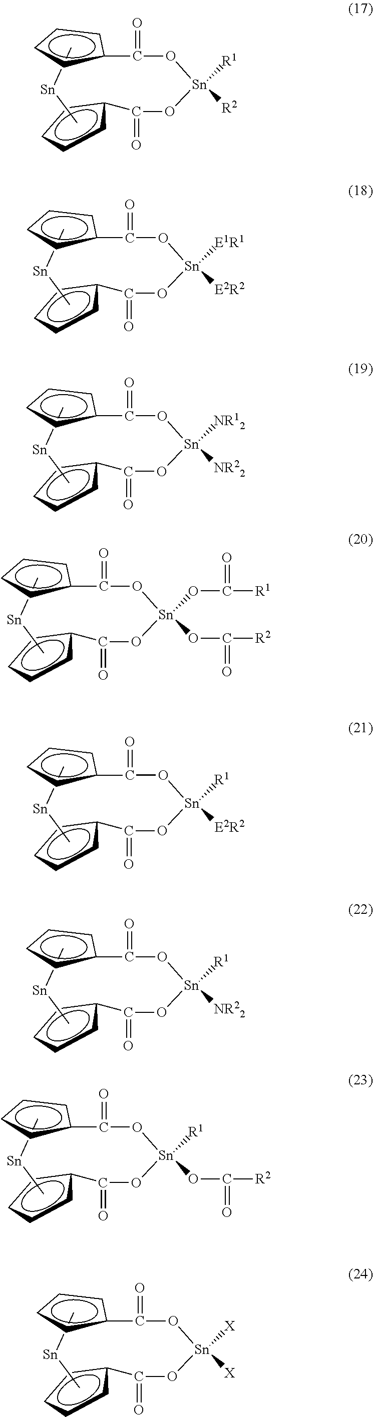

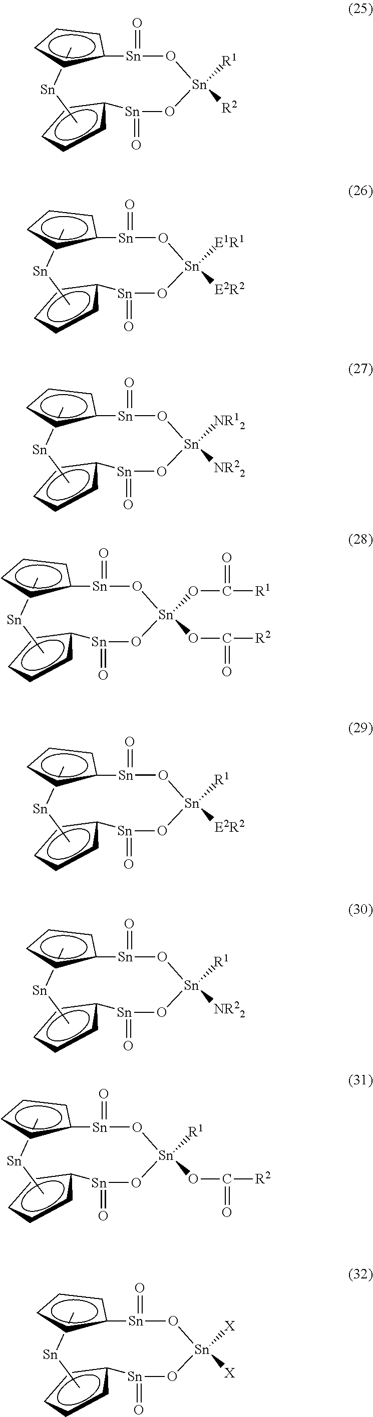

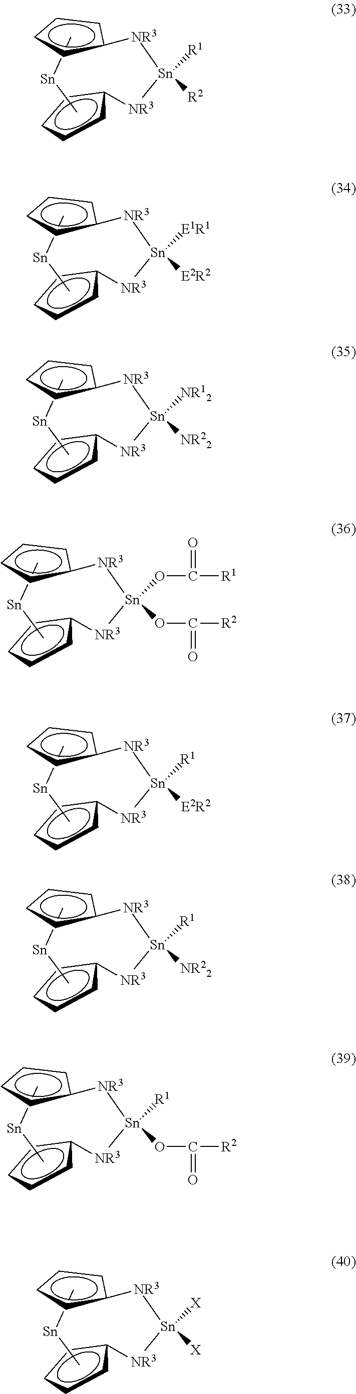

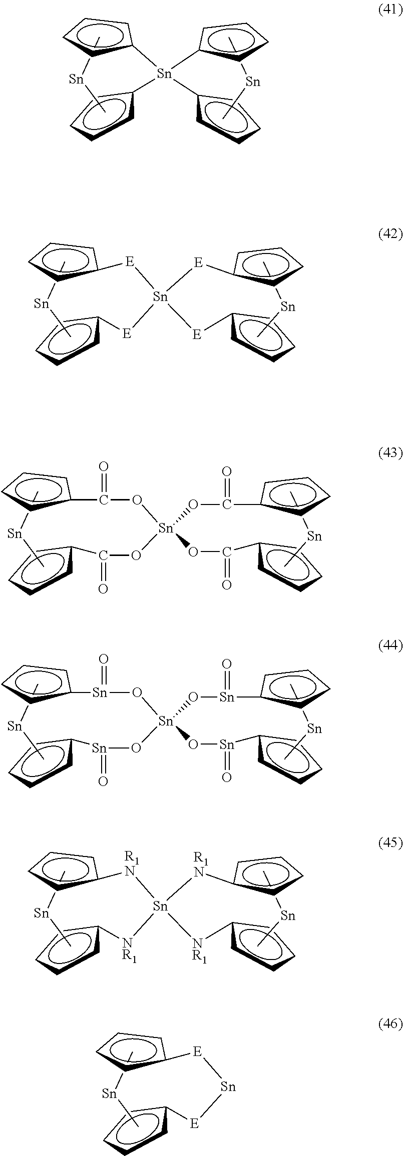

In some embodiments, organometallic compounds comprises cyclopentadienyl C₅H₅ group, or substituted C₅H₄R, C₅H₃R₂, C₅H₂R₃, C₅HR₄, or C₅R₅ group with hapticity of η¹, η², η³, η⁴, or η⁵, wherein R is H, a substituted and unsubstituted alkyl, alkenyl, alkynyl, or cycloalkyl group with 1 to 20 carbon atoms, or a substituted and unsubstituted aryl group with 6-20 carbon atoms, or an amino, cyano, ether, ester, halide, nitro, silyl, thiol, or carbonyl group. A person of ordinary skills in the art will recognize that the structures of cyclopentadienyl or substituted cyclopentadienyl with hapticity of η¹, η², η³, η⁴, or η⁵ of isomers within the explicit ranges of above are contemplated and are within the present disclosure.

Stannocenyl is sandwich metallocene bis(cyclopentadienyl)tin, or substituted bis(cyclopentadienyl)tin, wherein cyclopentadienyl is cyclopentadienyl C₅H₅ group, or substituted cyclopentadienyl C₅H₃R, C₅H₂R₂, C₅HR₃, C₅R₄, or C₅R₅ group, wherein R is H, a substituted or unsubstituted alkyl, alkenyl, alkynyl, or cycloalkyl group with 1 to 20 carbon atoms, or a substituted or unsubstituted aryl group with 6-20 carbon atoms, or an amino, cyano, ether, ester, halide, nitro, silyl, thiol, or carbonyl group, for example, methyl, ethyl, isopropyl, n-butyl, t-butyl, t-amyl, s-butyl, pentyl, hexyl, neopentyl, cyclohexyl, cyclopentyl, cyclobutyl, cyclopropyl, phenyl, or benzyl group.

R¹, R², R³ are each independently a substituted or unsubstituted C1-C20 alkyl group, such as methyl, ethyl, propyl, n-butyl, t-butyl group; a substituted or unsubstituted C3-C20 cycloalkyl group, such as cyclobutyl, methyl cyclobutyl, ethyl cyclobutyl, butyl cyclobutyl, cyclopentyl, methyl cyclopentyl, ethyl cyclopentyl, cyclohexyl, methyl cyclohexyle, ethyl cyclohexyl, cycloheptyl group, or cyclooctyl group; a substituted or unsubstituted C5-C20 cycloalkenyl group, such as cyclopentadienyl group, substituted cyclopentadienyl group, or cycloheptatrienyl group; a substituted or unsubstituted C6-C20 aryl group, such as phenyl, benzyl, ethyl benzyl, propyl benzyl, isopropyl benzyl, butyl benzyl, or t-butyl benzyl group.

In some embodiments, E, E¹, E² are each independently oxygen (O), sulfur (S), selenium (Se), or tellurium (Te). In some embodiments, X is one selected from the group of F, Cl, Br, or I.

As one of ordinary skill in the art will recognize, the chemical compounds listed here are merely intended as illustrated examples of the organotin compounds including clusters, and are not intended to limit the embodiments to only those organotin compounds specifically described. Rather, any suitable organotin compounds may be used, and all such organotin compounds are fully intended to be included within the scope of the present embodiments.

All chemical manipulations, including preparation and purification, are performed under an inert atmosphere of purified nitrogen or argon in dry and degassed solvents by employing standard Schlenk techniques. In the present disclosure, the purification methods include, but not limited to, distillation, extraction, filtration, recrystallization, column chromatography, coordination, sublimation, or combinations thereof. In some embodiments, recrystallization may result in single crystals, which are suitable for X-ray diffraction analysis to determine the molecular structures. In some embodiments, fractional distillation is used to purify the liquid products under reduced pressure. In some embodiments, column chromatography is required for isolation or purification the products.

In the present disclosure, organotin compounds represented by Chemical Formulas (1)-(46) may be synthesized according to appropriate methods.

In one example embodiment, stannocene (η⁵—C₅H₅)₂Sn is used as parent molecule for carrying out lithiation at one or two C₅ rings, such as mono-lithiation, or bi-lithiation, by strong bases, for example, methyllithium (MeLi), n-butyllithium (n-BuLi), s-butyllithium (s-BuLi), or t-butyllithium (t-BuLi), and then followed by further procedures to synthesize desired compounds. For example, in one example embodiment, bi-lithiation at two C₅ rings of stannocene are carried out by n-BuLi in THF at −78° C. to afford (η⁵—C₅H₄Li)Sn(η⁵—C₅H₄Li) (ScLi₂). In some embodiments, the addition of coordination reagents is required to improve the yields of bi-lithiation at two C₅ rings, for example, (N,N,N′,N′-tetramethyl-1,2-diaminotheane (TMEDA). A person of ordinary skills in the art will recognize that the synthetic strategies, reagents, solvents, or reaction conditions including reactant ratios, temperature, reaction time, or addition manner within the explicit ranges of above are contemplated and are within the present disclosure.

In an example embodiment, organotin compound ansa-bridged [1]stannocenophanes can be prepared according to the following method:

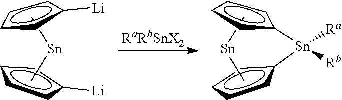

wherein R^{a}, R^{b} are each independently —R¹, -ER¹, —N(R¹)(R²), or —O—(C═O)R¹, wherein R¹, R² are each independently a substituted or unsubstituted alkyl, alkenyl, alkynyl, cycloalkyl, or cycloalkenyl group with 1 to 20 carbon atoms, or a substituted and unsubstituted aryl group with 6-20 carbon atoms; E=O, S, Se, or Te; X═F, Cl, Br, or I. A person of ordinary skills in the art will recognize that the synthetic strategies, reagents, solvents, or reaction conditions including reactant ratios, temperature, reaction time, or addition manner within the explicit ranges of above are contemplated and are within the present disclosure.

In another example embodiment, the represented bi-substituted (stannocenyl)tin compounds are prepared through the reactions of (η⁵—C₅H₄Li)Sn(η⁵—C₅H₄Li) (ScLi₂) with appropriate reagents under ambient conditions as Scheme 1 depicted. A person of ordinary skills in the art will recognize that the synthetic strategies, reagents, or reaction conditions including reactant ratios, temperature, reaction time, or addition manner within the explicit ranges of above are contemplated and are within the present disclosure.

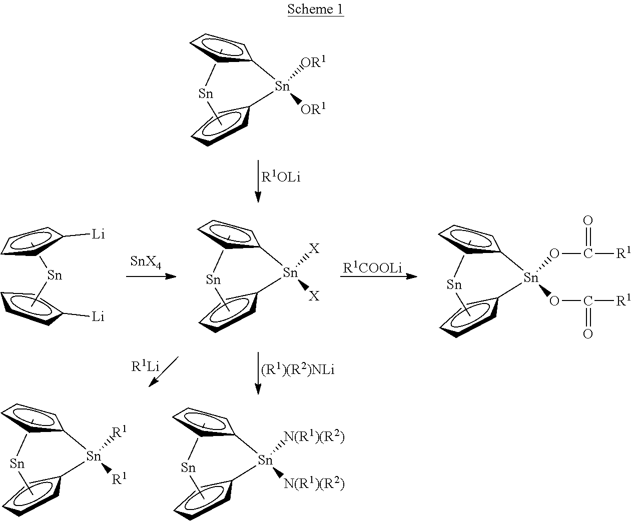

In one example embodiment, stannocenol (η⁵—C₅H₄OH)₂Sn can be prepared by the reaction of (η⁵—C₅H₄Li)₂Sn with (CH₃)₃SiOOSi(CH₃)₃ at −78° C. in THF, then followed by acidification or hydrolysis, which is according to the similar manner of the reference, C. Elschenbroich, F. Lu, H. Klaus, “[5]Trovacenol, (η⁷—C₇H₇)V(η⁵—C₅H₄OH): Synthesis and Structural Characterization”, Organometallics, 2002, 21 5152-5154, which is incorporated herein by reference. In some embodiments, (η⁵—C₅H₄OH)₂Sn may react with bases, for example, NaOH or n-BuLi, to form (η⁵—C₅H₄OLi)₂Sn, which may be used as the precursors for the further synthesis of organotin compounds. A person of ordinary skills in the art will recognize that the synthetic strategies, reagents, or reaction conditions including reactant ratios, temperature, reaction time, or addition manner within the explicit ranges of above are contemplated and are within the present disclosure.

In one example embodiment, (stannocenyl)chalcogenide and related derivates are prepared (as Scheme 2 depicted) according to the similar manner of the references, C. Elschenbroich, F. Lu, K. Harms, O. Burghaus, C. Pietzonka, J. Pebler, “α,ω-Di([5]trovacenyl) Sulfides TVC-Sn-TVC (n=1-4) and TVC-SCH₂S-TVC: a Study in Intramolecular Communication”, European Journal of Inorganic Chemistry, 2012, 3929-3936; F. Lu, “Elemental sulfur as soft oxidant for facile one-pot preparation of air-sensitive organometallic di[5]trovacenyldichalcogenides”, Inorganic Chemistry Communication, 37 (2013) 148-150; all of which are incorporated herein by references. A person of ordinary skills in the art will recognize that the synthetic strategies, reagents, or reaction conditions including reactant ratios, temperature, reaction time, or addition manner within the explicit ranges of above are contemplated and are within the present disclosure.

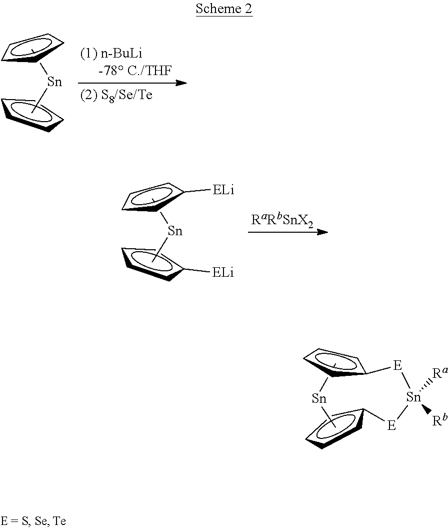

In one example embodiment, stannocenyl carboxylic acid (η⁵—C₅H₄COOH)₂Sn are synthesized by the reactions of (η⁵—C₅H₄Li)₂Sn with gaseous CO₂ to afford intermediates (η⁵—C₅H₄COOLi)₂Sn, then followed by acidified by HCl solution. In some embodiments, the as-formed intermediate (η⁵—C₅H₅)Sn(η⁵—C₅H₄COOLi) or (η⁵—C₅H₄COOLi)₂Sn may be used as the precursors for the further synthesis (as Scheme 3 depicted). A person of ordinary skills in the art will recognize that the synthetic strategies, reagents, or reaction conditions including reactant ratios, temperature, reaction time, or addition manner within the explicit ranges of above are contemplated and are within the present disclosure.

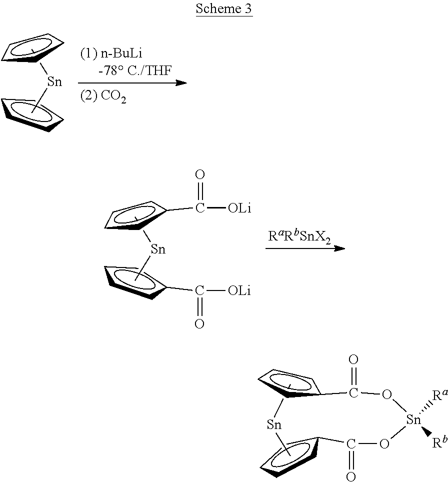

Cyclopentadienyl or substituted cyclopentadienyl group (C₅R₅, or Cp) may impart photosensitivity to the compounds, and the Cₚ—Sn bond formed may promote suitable solubility in an organic solvent to the organometallic sandwich and half-sandwich tin compounds. Accordingly, these Cₚ—Sn bond containing organometallic sandwich and half-sandwich tin compounds according to an embodiment may have improved sensitivity, resolution and stability, and may suitable for EUV photoresists, and/or the precursors for EUV lithography to form tin oxide or tin oxide hydroxide film.

Bridged-(stannocenyl)tin compounds contain cyclopentadienyl-Sn bond (Cₚ—Sn bond). Cₚ—Sn bond is sensitive to UV light and occurs the radiation disruption to generate free radical when exposures to UV light, which has been demonstrated, for example, P. J. Baker, A. G. Davies, M.-W. Tse, “The photolysis of cyclopentadienyl compounds of tin and mercury. Electron spin resonance spectra and electronic configuration of the cyclopentadienyl, deuteriocyclopentadienyl, and alkylcyclopentadienyl radicals”, Journal of Chemical Society, Perkin II, 1980, 941-948; S. G. Baxter, A. H. Cowley, J. G. Lasch, M. Lattman, W. P. Sharum, C. A. Stewart, “Electronic structures of bent-sandwich compounds of the main-group elements: A molecular orbital and UV photoelectron spectroscopic study of bis(cyclopentadienyl)tin and related compounds”, Journal of the American Chemical Society, 1982, 104, 4064-4069, all of which are incorporated herein by references. Baker, et. al. reported that the UV photolysis of unsubstituted sandwich and half-sandwich cyclopentadienyl-tin (IV) (C₅H₅—Sn) compounds, i.e., C₅H₅SnMe₃, C₅H₅SnBu₃, (C₅H₅)₂SnBu₂, C₅H₅SnCl₃, (C₅H₅)₂SnCl₂, (C₅H₅)₃SnCl, and (C₅H₅)₄Sn in toluene showed strong EPR spectra of the C₅H₅· radical. This study demonstrated cyclopentadienyl (C₅H₅) group or substituted cyclopentadienyl (C₅R₅) group has higher UV light photosensitivity compared with alkyl (e.g., methyl, butyl) groups under identical conditions. This property is beneficial to decrease EUV light dose and increase resolution.

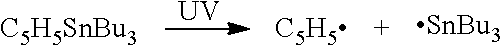

Bridged-(stannocenyl)tin compound photoresists containing cyclopentadienyl group, π bond, Cₚ—Sn bond, and/or related interaction may have excellent sensitivity to high energy radiation light (e.g., EUV), improved etch resistance, and resolution. Accordingly, the related solution compositions may have improved sensitivity and stability compared with organic polymer or inorganic photoresists.

Bridged-(stannocenyl)tin compound photoresists may have excellent sensitivity to EUV radiation light due to the tin adsorption high energy EUV ray at 13.5 nm (low expose dose photoresist, e.g., <20 mJ/cm²), and the disruption of Cp-Sn bond to form free radical, tin oxide and relative products, and toughness; low or free pattern defectivity at nanoscale. Accordingly, the solution composition of organometallic bridged-(stannocenyl)tin compound photoresist may have tight pitch (e.g., <10 nm), and may sustain the yield and deliver high resolution.

In some embodiments, bridged-(stannocenyl)tin compound photoresists may contain various functional groups, including but not limited to, ether, thiol, silyl, keto, cyano, carbonyl, or halogenated groups, or combinations thereof.

In some embodiments, the invention pertains to bridged-(stannocenyl)tin compound photoresists, for example, but not limited to, oxide hydroxide, carboxylate, alkoxide, amide, ester, or oxo, containing Sn—C, Sn—O, Sn—S, Sn—Se, or Sn—Te bond.

In some embodiments, bridged-(stannocenyl)tin compound photoresists according to embodiments of the present disclosure may be represented by at least one of examples. Examples of specific bridged-(stannocenyl)tin compound photoresists or precursor materials that may be used in implementations of the invention are represented by the above chemical formulas (1)-(46).

In some embodiments, bridged-(stannocenyl)tin compound photoresists are soluble in appropriate organic solvents for further photolithography pattern processing like spin-on coating. The solution compositions of organometallic photoresists can be formed by dissolving bridged-(stannocenyl)tin compound photoresists in organic solvents, including but not limit to, chloroform, tetrahydrofuran, dimethoxyethane, dimethylformamide, dimethyl sulfoxide, alcohols (e.g., 4-methyl-2-pentenol, ethanol, methanol, propanol, isopropanol, butanol), benzene, toluene, xylene, carboxylic acid, ethers (e.g., tetrahydrofuran, anisole), esters (e.g., ethyl acetate, ethyl lactate, butyl acetate), ketone (e.g., 2-heptanone, methyl ethyl ketone), or two or more mixtures thereof or the like. The solution composition of bridged-(stannocenyl)tin compound photoresist can be utilized for photolithography like EUV, DUV for further processing and patterning. A person of ordinary skills in the art will recognize that the choice of solvents and solution composition components within the explicit ranges of above are contemplated and are within the present disclosure.

In some embodiments, the solubility of bridged-(stannocenyl)tin compound photoresists in organic solvents may be improved, and dissolution during an extreme ultraviolet exposure. Accordingly, a nanoscale pattern having improved sensitivity and limited resolution may be afforded. Additionally, the as-formed pattern may not collapse while having a high aspect ratio.

In some embodiments, bridged-(stannocenyl)tin compound photoresist composition may also contain an additive.

In some embodiments, the additive may be organic thiol, organic alcohol, organic amine, organic amide, organic carboxylic acid, organic phosphine, organic phosphine oxide, organic phosphonic acid, or combinations thereof.

In some embodiments, the additive comprises: 1-dodecanethiol, 2-dodecanethiol, 1,12-dodecanedithiol, 1-dodecanol, 1-octanol, 1-hexadecanol, 1-heptadecyloctadecylamine, decylamine, dodecylamine, decanamide, docosanamide, dodecanamide, oleic acid, citric acid, decanoic acid, hexadecanedioic acid, trioctylphosphine, tributylphosphine, trioctylphospine oxide, hexylphosphonic acid, octadecylphosphonic acid, 11-undecenyl phosphonic acid, or combinations thereof.

In the present disclosure, a method of forming photolithography pattern comprises: depositing organometallic bridged-(stannocenyl)tin compound photoresist over a substrate to form photoresist layer; in some embodiments under oxygen-source atmosphere to form organotin photoresist layer; exposing the formed photoresist layer to actinic radiation to form a latent pattern; and then developing the latent pattern by applying a developer, or sublimation, or evaporation, to remove the selected portion of photoresists to form a photolithography pattern.

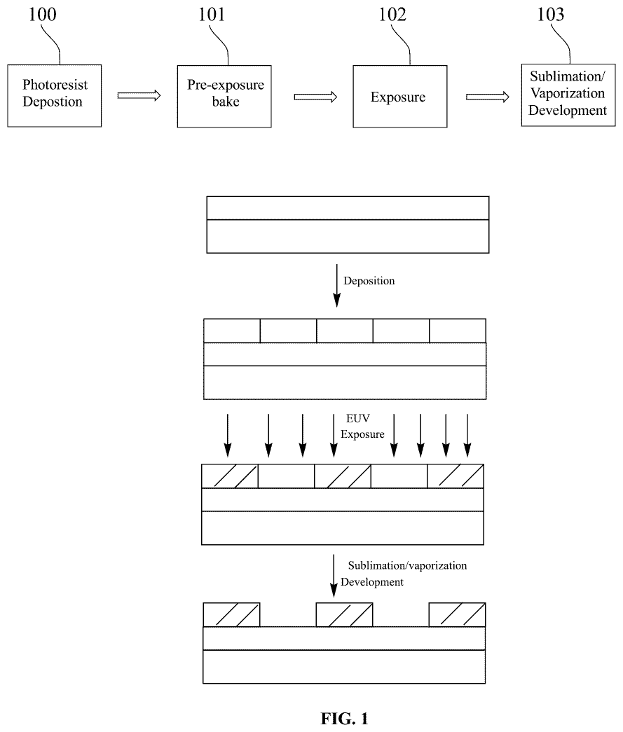

FIG. 1 is a flowchart of photolithography patterning process including organotin photoresist composition depositing over a substrate 100 to form a thin photoresist layer; after pre-exposure baking 101, the formed layer exposing to actinic radiation (e.g., EUV) to form a latent image 102; the latent developed by sublimation or vaporization 103, to form a developed photolithography pattern.

In some embodiments, bridged-(stannocenyl)tin compound photoresist composition may be deposited on the surface of semiconductor substrate by wet or dry coating methods. The general wet coating methods include spin-on coating, spray coating, dip coating, vapor deposition, knife edge coating, inkjet printing, screen printing, or the like.

In some embodiments, the conventional spin-on coating method is used for deposition of organometallic photoresists on the surface of semiconductor substrates to form a thin film for photolithography. Under this circumstance, the followed procedure of post-apply backed (PAB) on a hot plate at ambient temperature (e.g., 100 C°) under inert atmosphere (e.g., dinitrogen) with regular pressure will be controlled, in order to avoid potential photoresist sublimation at the point temperature, and decrease the thickness of photoresist, along with defects or collapses.

In some embodiments, sublimation or evaporation is applied for deposition of organotin compound photoresist over the substrate. The sublimized ability and physical properties of organotin photoresist determines the availability and quality of deposited layer on the substrate.

In some embodiments, bridged-(stannocenyl)tin compounds photoresists may be deposited on the semiconductor substrate through dry deposition method, such as chemical vapor deposition (CVD), physical vapor deposition (PVD), or atomic layer deposition (ALD).

In some embodiments, chemical vapor deposition, physical vapor deposition, or atomic layer deposition methods may improve the uniformity of thickness and composition, and reduce the photoresist film defect density.

In some embodiments, bridged-(stannocenyl)tin compounds or precursors, which are suitable for chemical vapor deposition, physical vapor deposition, or atomic layer deposition, can form metal oxide film through photolithography patterning.

The formed photoresist layer is then conducted to selectively exposure to actinic radiation to form exposed regions and unexposed regions with different properties, for example, the exposed regions form metal oxide or poly metal oxide with poor solubility in organic solvents, which also cannot be sublimized or evaporated under high vacuum (e.g., ranging from 0.00001-100 torr) and temperature (e.g., ranging from 20-300° C.). Meanwhile, the unexposed regions can be developed or removed by organic solvents as wet development, or gases like Cl₂, CH₂Cl₂, BF₃, BCl₃, CF₄, CCl₄, HBr, or others as dry development, or sublimation or evaporation under vacuum (e.g., ranging from 0.00001-100 torr) and temperature (e.g., ranging from 20-300° C.).

In some embodiments, the actinic radiation is ultraviolet radiation, far ultraviolet radiation (FUV), extreme ultraviolet radiation (EUV), deep ultraviolet radiation (DUV), e-beam radiation, X-ray radiation, or ion-beam radiation. In some embodiments, the radiation source is one or more of, a mercury vapor lamp, xenon lamp, a KrF excimer laser light (248 nm), an ArF excimer laser light (193 nm), or CO₂ laser excited Sn plasm (13.5 nm).

In some embodiments, after exposure to actinic radiation, the exposed and unexposed portion of bridged-(stannocenyl)tin compound photoresists possess different chemical and physical properties. Exposed portion of bridged-(stannocenyl)tin compound photoresists absorb ultraviolet radiation, then organic ligand groups can cleave from bridged-(stannocenyl)tin compound photoresists to form metal oxide or polymetallic oxide/oxo pattern.

In some embodiments, a post-exposure baking is carried out at a temperature ranging of 50-300° C. In some embodiments, the post-exposure baking is performed to afford the crosslink reaction over the substrate under ambient condition, for example, under reactive gaseous atmosphere or oxygen source atmosphere.

In some embodiments, the exposed portion of bridged-(stannocenyl)tin compound photoresist can be conducted by dry etch processing using dry BCl₃ plasma, hydrogen halides, hydrogen gas, or halogen gas.

The development process is to either remove the exposed portion to form the positive tone pattern or unexposed portion to form negative tone pattern by different developer compositions. The contact of the pattered coating material or latent image with developer solvents will perform the target.

In some embodiments, the general wet developer compositions can be neutral, basic, acidic aqueous solutions, or organic solvents at low to high concentrations. The temperature for development process can be high or low. The temperature can be applied for the control of the rate or kinetics of development process as required.

In some embodiments, the general wet liquid solvent developer composition comprises an organic solvent blend. Non-limiting examples of organic solvents used in the method of forming patterns according to an embodiment may include, but not limited to, ketones (e.g., acetone, 2-heptanone, methylethylketone, cyclohexanone, 2-pyrrolidone, 1-ethyl-2pyrrolidone, and/or the like), alcohols (e.g., methanol, ethanol, 1-propanol, isopropanol, 1-butanol, 4-methyl-2-propanol, 1,2-propanediol, 1,2-hexanediol, 1,3-propanediol, pentanol, 2-heptanol, and/or the like), esters (e.g., ethyl acetate, n-butyl acetate, butyrolactone, propylene glycol methyl ether, ethylene glycol, propylene glycol, glycerol, ethylene glycol methyl ether, and/or the like), aromatic solvents (e.g., benzene, toluene, xylene), acid (e.g., formic acid, acetic acid, oxalic acid, 2-ethylhexanonic acid), or combinations thereof.

In some embodiments, the developer for selectively removal of exposed or unexposed photoresist is an organic solvent, including but not limited to, benzene, toluene, xylene, pentane, hexane, cyclohexane, tetrahydrofuran, dimethoxyethane, methanol, ethanol, propanol, butanol, diethyl ethers, anisole, ethyl acetate, ethyl lactate, butyl acetate, or combinations thereof.

In some embodiments, the wet liquid solvent developing process is applied by dipping the exposed or unexposed substrates into a developer bath. In some embodiments, the wet solvent developing solution can be sprayed into the exposed or unexposed photoresists layer.

In some embodiments, the developing method includes sublimation, or evaporation to remove unexposed sublimized-available bridged-(stannocenyl)tin compound photoresist. The properties of bridged-(stannocenyl)tin compound photoresists, such as sublimation ability or thermostability, play the key role in determining the development method with particular stability and processing effectiveness for radiation absorption.

In some embodiments, bridged-(stannocenyl)tin compound photoresists may be sublimized or vaporized under ambient vacuum (e.g., ranging from 0.00001 torr to 100 torr) and temperature (e.g., ranging from 20 to 300° C.) without decomposition. After exposure to actinic radiation, the unexposed bridged-(stannocenyl)tin compound photoresist may be removed by sublimation or evaporation, while the exposed portion of bridged-(stannocenyl)tin compound photoresist may not be sublimized or vaporized under ambient vacuum and temperature.

In some embodiments, sublimation or vaporization development method overcomes the disadvantages from wet development methods, such as dipping in organic solvents or aqueous solutions for development, washing by solvents for removal, potential pattern collapses and defects due to the washings, related higher cost, waste solvents treatment, or environmental concerns.

In some embodiments, the bridged-(stannocenyl)tin compounds represented by chemical formulas (1)-(46) also may be applied as the precursors for the formation of photoresist lay over a substrate, and then for photolithographic patterning.

In some embodiments, the photoresist layers over the substrate may be formed by the reactions of bridged-(stannocenyl)tin compounds under oxygen source atmosphere. Then after irradiation, the radiation reaction will occur to form oxide, oxo, or hydroxyl network products. Meanwhile, unexposed portion would not convert to oxide, oxo, or hydroxyl network products, and may be removed by sublimation or vaporization under high vacuum and temperature. In some embodiments, oxygen source atmosphere includes but not limited to water, oxygen, extreme clean dry air, ozone, hydrogen peroxide, or likewise, or combinations thereof.

In some embodiments, bridged-(stannocenyl)tin compounds may form organotin clusters under oxygen-source atmosphere, such as water vapor. Organotin clusters may be ultraviolet sensitive, but may not be volatile for sublimation or vaporization.

In some embodiments, the sublimation or vaporization development method may also be suitable for patterning at >10 nm, such as DUV, or FUV. The residual, radiated, or unirradiated photoresist among pattern features may be selectively removed. This requires radiation sensitive bridged-(stannocenyl)tin compound photoresist at the levels suitable for DUV or FUV, according to E=hv=hc/λ and BDE (M-C), wherein E represents energy, h is plank constant, v is frequency, c is light speed, and k is light wave length.

In some embodiments, a blend of bridged-(stannocenyl)tin compound photoresists can be carried out in situ ultraviolet light-induced radiation reaction to form non-sublimized, or insoluble complexes, including but not limited to oxo/hydroxyl, polyatomic complexes, metal oxo or hydroxyl network, or organometallic polymer, which possess the feature characterizes for small pitch like <7 nm. Meanwhile, unexposed portion of the blend bridged-(stannocenyl)tin compound photoresist can be removed by sublimation under high vacuum and ambient temperature.

In some embodiments, the in situ radiation reaction may be carried out in organic or aqueous solvents, which is spray over the substrate surface after deposition of bridge-(stannocenyl)tin compound photoresist, or by spinning-on deposition as solution composition.

In addition, bridged-(stannocenyl)tin compound photoresists patterning according to an embodiment is not necessarily limited to the negative tone image but may be formed to have a positive tone image.

Hereinafter, the present invention is described in more detail through Examples regarding the preparation of bridged-(stannocenyl)tin compound photoresist composition of the present embodiments. However, the present invention is not limited by the Examples.

### EXAMPLES

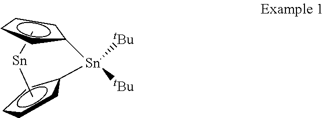

Synthesis of Sn(η⁵—C₅H₄)₂Sn^{t}Bu₂. At −78° C., a solution of ^{t}Bu₂SnCl₂ (1.11 g, 3.66 mmol) in diethyl ether (50 mL) was added dropwise to a solution of [(η⁵—C₅H₄Li]₂Sn (from 0.91 g/3.66 mmol stannocene, and 4.6 mL/1.6 M, 7.36 mmol n-BuLi) in THF (100 mL) with vigorously stirring. After stirring for hours, the reaction solution was filtered. The filtrate was evaporated in vacuo to give the titled product. Yield: 1.36 g, 77%. MS (EI): m/z 480 (M⁺). ¹H NMR (400 MHz, CDCl₃) δ=1.23 (s, 18H), 6.21 (m, 4H), 6.63 (m, 4H). Elemental analysis of C₁₈H₂₆Sn₂ (479.60), anal. calculated: C, 45.08; H: 5.42; and found: C, 45.12; H, 5.68.

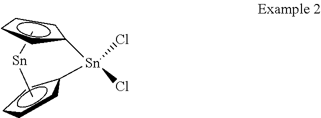

Synthesis of Sn(η⁵—C₅H₄)₂SnCl₂. Sn(η⁵—C₅H₄)₂SnCl₂. At −78° C., SnCl₄ (0.55 mL, 4.69 mmol) in hexane (10 mL) was added dropwise to a solution of [(η⁵—C₅H₄Li]₂Sn (from 1.16 g/4.66 mmol stannocene, and 5.83 mL/1.6 M, 9.33 mmol n-BuLi) in Et₂O (100 mL) with vigorously stirring (Caution: SnCl₄ is extremely hydrolytic when exposure to air or water and releasing HCl gaseous !!!). After stirring for one hour, the solution was filtered through Celite. The filtrate was evaporated in vacuo to give the titled product. Yield: 1.43 g, 70%. MS (EI): m/z 436 (M⁺).

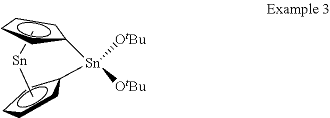

Synthesis of Sn(η⁵—C₅H₄)₂Sn(O^{t}Bu)₂. At −78° C., t-BuOK (1.046 g, 9.33 mmol) was added to the solution of Sn(η⁵—C₅H₄)₂SnCl₂ (from 1.16 g/4.66 mmol stannocene, 5.83 mL/1.6 M, 9.33 mmol n-BuLi, and 0.55 mL SnCl₄) in THF (100 mL) with vigorously stirring. After stirred for 6 hours and removal of all the solvents, the residue was extracted by ether and filtered through Celite. The filtrate was evaporated in vacuo to give the product. Yield: 1.19 g, 50%. ¹H NMR (400 MHz, CDCl₃) δ=1.36 (s, 18H), 6.23 (m, 4H), 6.62 (m, 4H). 5.90 (s, I0H), MS (EI): m/z 512 (M⁺).

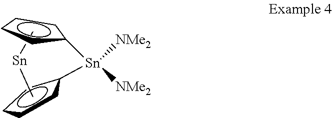

Synthesis of Sn(η₅—C₅H₄)₂Sn(NMe₂)₂. At −78° C., LiN(CH₃)₂(178 mg, 3.50 mmol) was added to the solution of Sn(η⁵—C₅H₄)₂SnCl₂ (766 mg, 1.76 mmol) in Et₂O (100 mL) with vigorously stirring. After stirred overnight, the solution was filtered through Celite and the filtrate was evaporated in vacuo to give the titled product. Yield: 0.46 g, 62%. MS (EI): m/z 423 (M⁺).

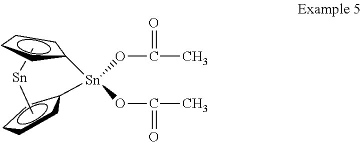

Synthesis of Sn(η⁵—C₅H₄)₂Sn(OCOCH₃)₂. At −78° C., CH₃COONa (262 mg, 3.2 mmol) was added to the solution of Sn(η⁵—C₅H₄)₂SnCl₂ (696 mg, 1.6 mmol) in Et₂O (100 mL) with vigorously stirring. After stirred overnight, the solution was filtered through Celite. The filtrate was evaporated in vacuo to give the titled product. Yield: 426 mg, 53%. MS (EI): m/z 483 (M⁺).

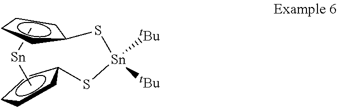

Synthesis of Sn(η⁵—C₅H₄S)₂SnₜBu₂. At 0° C., a solution of ^{t}Bu₂SnCl₂ (1.05 g, 3.46 mmol) in diethyl ether (50 mL) was added dropwise to a solution of [(η⁵—C₅H₄SLi]₂Sn (from 860 mg/3.46 mmol stannocene, 4.32 mL/1.6 M, 6.91 mmol n-BuLi, and 221 mg/6.92 mmol S₈) in Et₂O (100 mL) with vigorously stirring. After stirring for hours, the solution was filtered through Celite. The filtrate was evaporated in vacuo to give the product. Yield: 1.16 g, 62%. ¹H NMR (400 MHz, CDCl₃) δ=1.22 (s, 18H), 6.45 (m, 4H), 6.79 (m, 4H). MS (EI): m/z 544 (M⁺). Elemental analysis of C₁₈H₂₆S₂Sn₂ (543.60), anal. calculated: C, 39.77; H, 4.78; and found: C, 39.92; H, 5.11.

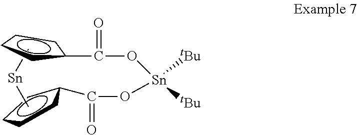

Synthesis of Sn(η⁵—C₅H₄COO)₂Sn^{t}Bu₂. At −78° C., a solution of ^{t}Bu₂SnCl₂ (1.09 g, 3.6 mmol) in diethyl ether (50 mL) was added dropwise to a solution of [(η⁵—C₅H₄COOLi]₂Sn (from 896 mg/3.6 mmol stannocene, and 4.5 mL/1.6 M, 7.2 mmol n-BuLi) in Et₂O (100 mL) with vigorously stirring. After stirring overnight, the reaction solution was filtered through Celite. The filtrate was evaporated in vacuo to give the titled product. Yield: 1.22 g, 60%. ¹H NMR (400 MHz, CDCl₃) δ=1.21 (s, 18H), 5.81 (m, 4H), 5.95 (m, 4H). MS (EI): m/z 568 (M⁺). Elemental analysis of C₂₀H₂₆O₄Sn₂ (567.62), anal. calculated: C, 42.32; H, 4.58; and found: C, 42.62; H, 4.90.

It is understood that the above described examples and embodiments are intend to be illustrative purpose only. It should be apparent that the present invention has described with references to particular embodiments, and is not limited to the example embodiment as described, and may be variously modified and transformed. A person with ordinary skill in the art will recognize that changes can be made in form and detail without departing from the sprit and scope of this invention. Accordingly, the modified or transformed example embodiments as such may be understood from the technical ideas and aspects of the present invention, and the modified example embodiments are thus within the scope of the appended claims of the present invention and equivalents thereof.

What is claimed is:

1. An organotin photoresist composition, comprising:
a bridged-(stannocenyl)tin compound, a solvent, and/or an additive;
wherein the bridged-(stannocenyl)tin compound is one or more selected from the following: 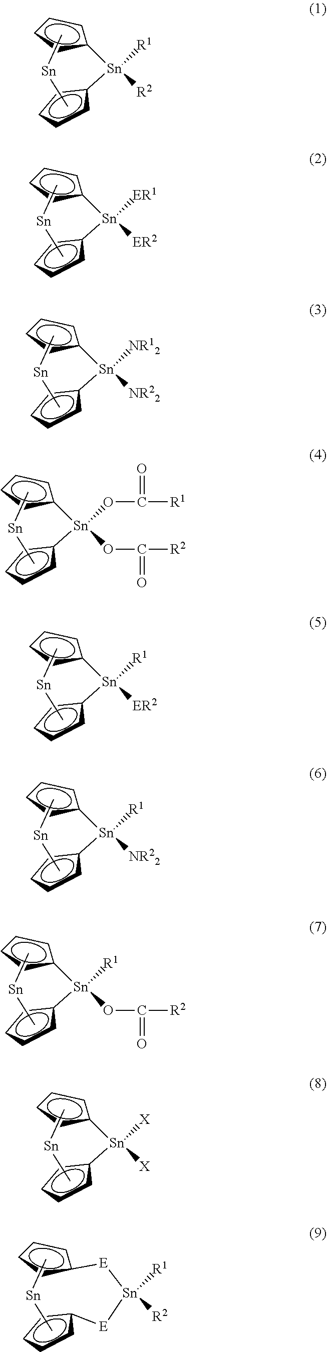 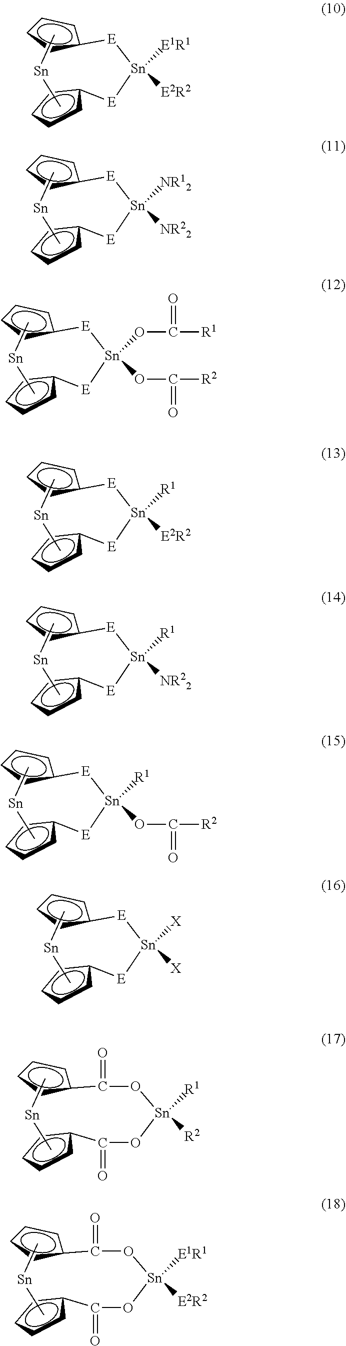 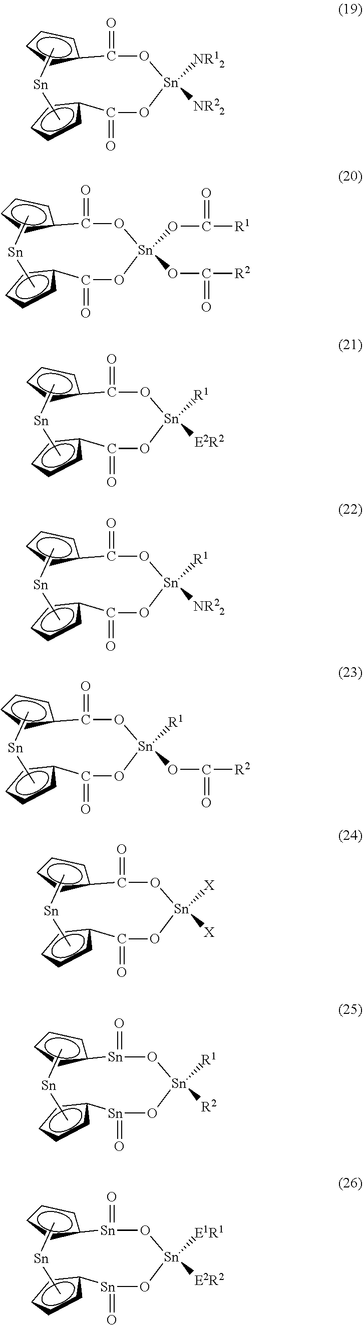 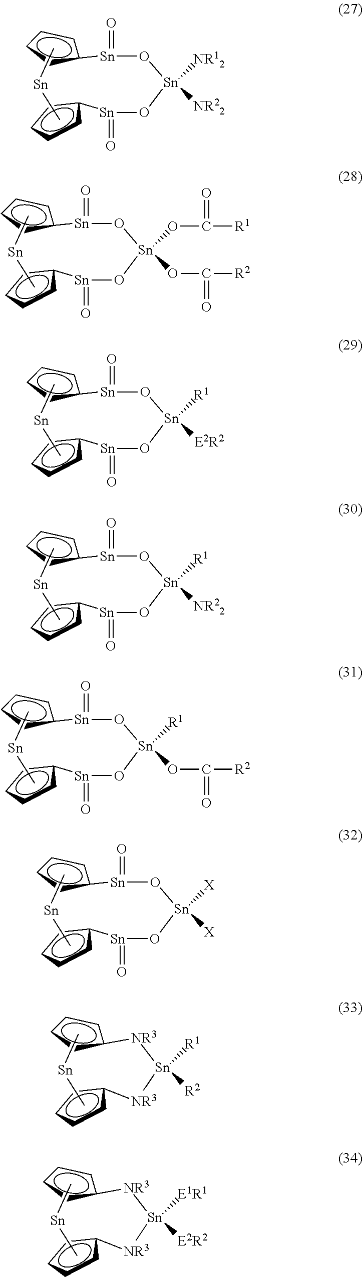 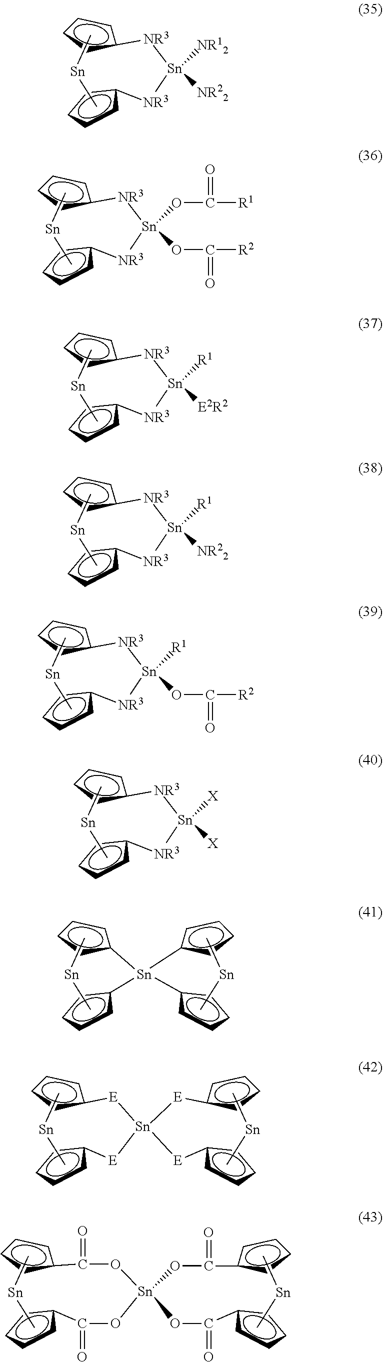 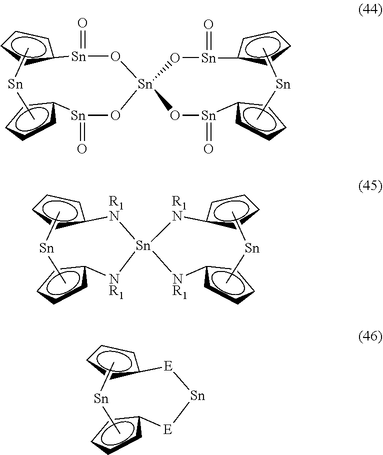
wherein R¹, R², R³ are each independently substituted and unsubstituted alkyl, alkenyl, alkynyl, cycloalkyl, or cycloalkenyl group with 1 to 20 carbon atoms, or substituted and unsubstituted aryl group with 6-20 carbon atoms, E, E¹, E² are each independently O, S, Se, or Te, X═F, Cl, Br, or I.

2. The organotin photoresist composition of claim 1, wherein stannocenyl is bis(cyclopentadienyl)tin, or substituted bis(cyclopentadienyl)tin, wherein cyclopentadienyl comprising cyclopentadienyl C₅H₅ group, or substituted cyclopentadienyl C₅H₃R, C₅H₂R₂, C₅HR₃, or C₅R₄ group with hapticity of η¹, η², η³, η⁴, or η⁵ of isomers, wherein R is H, a substituted and unsubstituted alkyl, alkenyl, alkynyl, or cycloalkyl group with 1 to 20 carbon atoms, or a substituted and unsubstituted aryl group with 6-20 carbon atoms, or an amino, cyano, ether, ester, halide, nitro, silyl, thiol, or carbonyl group.

3. The organotin photoresist composition of claim 1, wherein cycloalkenyl group comprises a substituted and unsubstituted C4 to C8 cyclic aliphatic unsaturated organic groups including at least one double bond.

4. The organotin photoresist composition of claim 1, wherein the additive comprises organic thiol, organic alcohol, organic amine, organic amide, organic carboxylic acid, organic phosphine, organic phosphine oxide, organic phosphonic acid, or combinations thereof.

5. The organotin photoresist composition of claim 4, wherein the additive comprises 1-dodecanethiol, 2-dodecanethiol, 1,12-dodecanedithiol, 1-dodecanol, 1-octanol, 1-hexadecanol, 1-heptadecyloctadecylamine, decylamine, dodecylamine, decanamide, docosanamide, dodecanamide, oleic acid, citric acid, decanoic acid, hexadecanedioic acid, trioctylphosphine, tributylphosphine, trioctylphospine oxide, hexylphosphonic acid, octadecylphosphonic acid, 11-undecenyl phosphonic acid, or combinations thereof.

6. The organotin photoresist composition of claim 1, wherein the solvent comprises chloroform, tetrahydrofuran, dimethoxyethane, ethanol, methanol, propanol, isopropanol, butanol, benzene, toluene, xylene, or combinations thereof.

7. A method of forming photolithography pattern, comprising;
depositing organotin compound photoresist over a substrate to form a layer,
wherein the organotin compound is bridged-(stannocenyl)tin compound;
exposing the organotin photoresist layer to actinic radiation to form a latent pattern; and
developing the latent pattern by applying a developer, or sublimation to remove the selected portion of photoresists to form a photolithography pattern.

8. The method of claim 7, wherein the bridged-(stannocenyl)tin compound is one or more selected from the following: 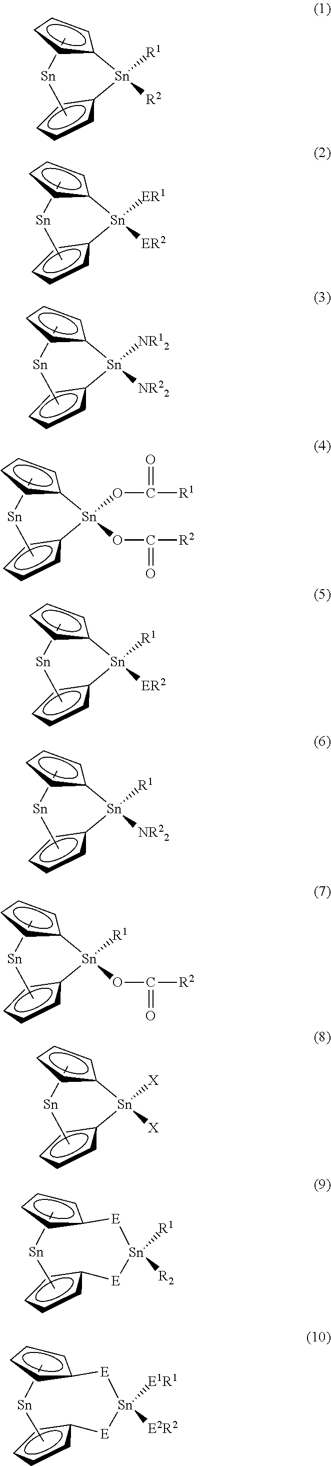 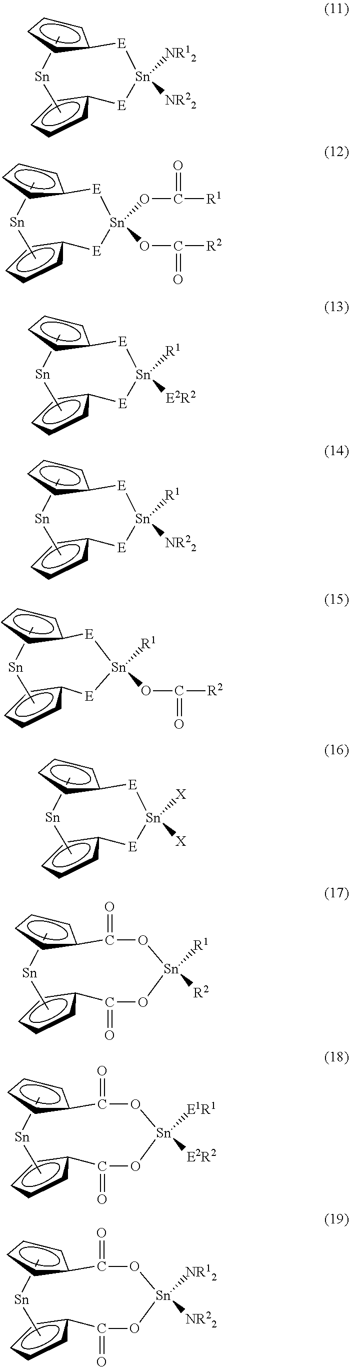 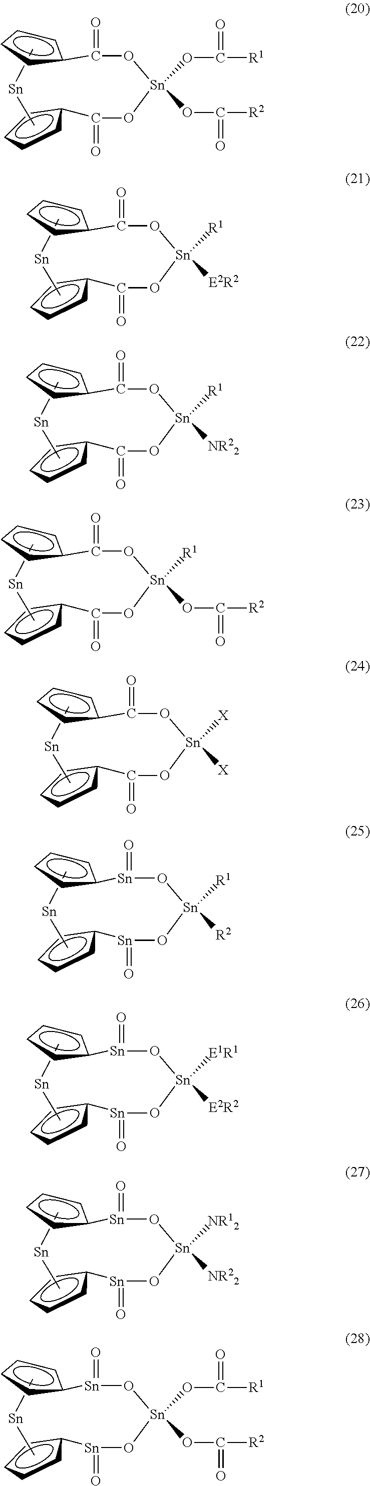 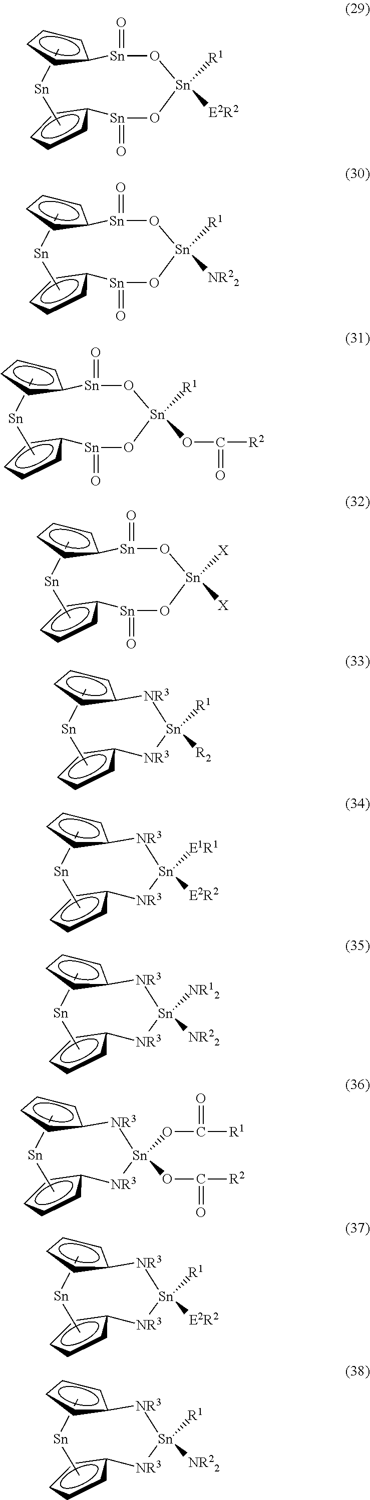 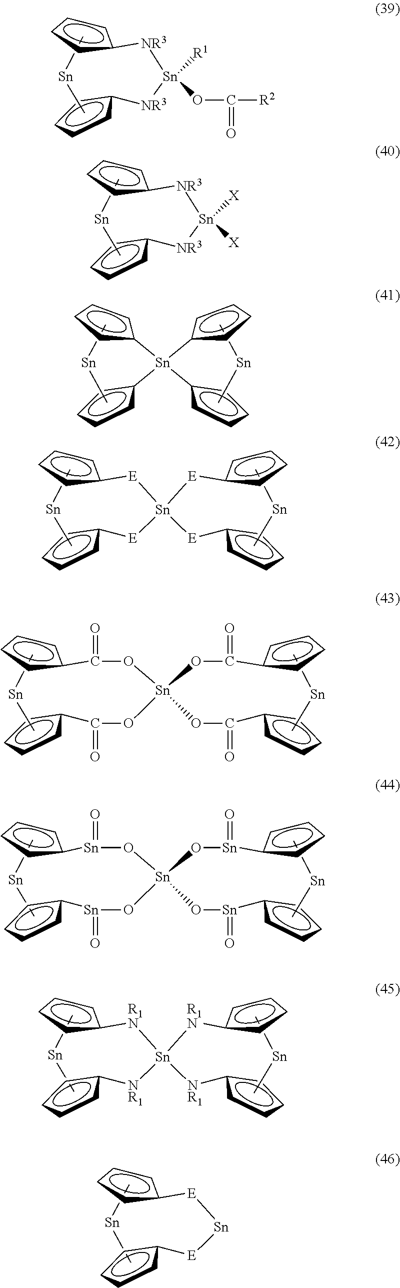
wherein R¹, R², R³ are each independently substituted and unsubstituted alkyl, alkenyl, alkynyl, cycloalkyl, or cycloalkenyl group with 1 to 20 carbon atoms, or substituted and unsubstituted aryl group with 6-20 carbon atoms, E, E¹, E² are each independently O, S, Se, or Te, X═F, Cl, Br, or I.

9. The method of claim 7, wherein stannocenyl is bis(cyclopentadienyl)tin, or substituted bis(cyclopentadienyl)tin, wherein cyclopentadienyl comprising cyclopentadienyl C₅H₅ group, or substituted cyclopentadienyl C₅H₃R, C₅H₂R₂, C₅HR₃, or C₅R₄ group with hapticity of η¹, η², η³, η⁴, or η⁵ of isomers, wherein R is H, a substituted and unsubstituted alkyl, alkenyl, alkynyl, or cycloalkyl group with 1 to 20 carbon atoms, or a substituted and unsubstituted aryl group with 6-20 carbon atoms, or an amino, cyano, ether, ester, halide, nitro, silyl, thiol, or carbonyl group.

10. The method of claim 8, wherein cycloalkenyl group comprises a substituted and unsubstituted C4 to C8 cyclic aliphatic unsaturated organic groups including at least one double bond.

11. The method of claim 7, wherein depositing organotin compound photoresist over a substrate is by spin-on coating, spray coating, chemical vapor deposition, physical vapor deposition, or atomic layer deposition.

12. The method of claim 7, wherein the actinic radiation is extreme ultraviolet radiation, deep ultraviolet radiation, KrF (248 nm), ArF (193 nm), e-beam radiation, X-ray radiation, or ion-beam radiation.

13. The method of claim 7, wherein the developer comprises benzene, toluene, xylene, pentane, hexane, cyclohexane, tetrahydrofuran, dimethoxyethane, methanol, ethanol, propanol, butanol, diethyl ethers, anisole, ethyl acetate, ethyl lactate, butyl acetate, or combinations thereof.

14. An organotin compound, having a chemical structure bearing bridged-stannocenyl group selected from the following: 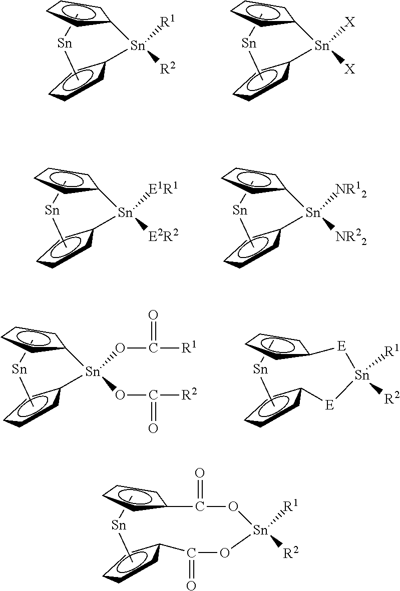
wherein R¹, R² are each independently substituted and unsubstituted alkyl, alkenyl, alkynyl, cycloalkyl, or cycloalkenyl group with 1 to 20 carbon atoms, or substituted and unsubstituted aryl group with 6-20 carbon atoms, E, E¹, E² are each independently O, S, Se, or Te, X═F, Cl, Br, or I.

15. The organotin compound of claim 14, wherein stannocenyl is bis(cyclopentadienyl)tin, or substituted bis(cyclopentadienyl)tin, wherein cyclopentadienyl comprising cyclopentadienyl C₅H₅ group, or substituted cyclopentadienyl C₅H₃R, C₅H₂R₂, C₅HR₃, or C₅R₄ group with hapticity of η¹, η², η⁴, or η⁵ of isomers, wherein R is H, a substituted and unsubstituted alkyl, alkenyl, alkynyl, or cycloalkyl group with 1 to 20 carbon atoms, or a substituted and unsubstituted aryl group with 6-20 carbon atoms, or an amino, cyano, ether, ester, halide, nitro, silyl, thiol, or carbonyl group.

16. The organotin compound of claim 15, wherein R is H, alkyl, or aryl group.

17. The organotin compound of claim 16, wherein R is H, methyl, ethyl, propyl, n-butyl, t-butyl, phenyl, or benzyl group.

18. The organotin compound of claim 14, wherein R¹, R² are alkyl, cycloalkenyl, or aryl group.

19. The organotin compound of claim 18, wherein R¹, R² are methyl, ethyl, propyl, n-butyl, t-butyl, cyclopentadienyl, phenyl, or benzyl group.

20. The organotin compound of claim 14, wherein X═Cl.
